(19) United States
(12) Patent Application Publication
(10) Pub. No.: US 2005/0202323 A1
(43) Pub. Date: Sep. 15, 2005

(54) Phase shift mask and method of manufacturing phase shift mask

(75) Inventor: Kunio Watanabe, Nara (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Semiconductor Leading Edge Technologies, Inc., Tsukuba-shi (JP)

(21) Appl. No.: 11/022,700

(22) Filed: Dec. 28, 2004

(30) Foreign Application Priority Data
Mar. 11, 2004 (JP) 2004-068302

(51) Int. Cl. G03F 9/00

(52) U.S. Cl. 430/5

(57) ABSTRACT

A phase shift mask comprises a transparent substrate and a light shielding film. The transparent substrate has two regions that transmit exposure light. The exposure light transmitted through one region having a phase that is inverted in a recessed portion formed in the other region. The light shielding film shields the exposure light. The light shielding film is formed on the transparent substrate with a plurality of film thicknesses and has an edge that does not hang over the recessed portion.

### CROSS-REFERNCE TO ERLATED APPLICATIONS

This application is based upon and claims the benefit of priority from the prior Japanese Patent Application No. 2004-068302, filed on Mar. 11, 2004; the entire contents of which are incorporated herein by reference.

### BACKGROUND OF THE INVENTION

The invention relates to a phase shift mask or a method of manufacturing a phase shift mask. In particular, the invention relates to the structure of a phase shift mask used in a photolithography apparatus, a method of manufacturing the same, and a method of exposing the same.

Recent semiconductor technologies have advanced the scaling of semiconductor integrated circuit patterns, and the design rule of circuit components and wirings is decreasing below the 100-nm level. In photolithography used in this case, for example, short-wavelength light such as F₂ laser light (wavelength 157 nm) is used to transfer an integrated circuit pattern on a photomask onto a semiconductor wafer.

FIGS. 11A through 11C show a conventional photomask and its optical amplitude and optical intensity distribution.

FIG. 11A shows a cross-sectional shape of a binary mask 101 serving as a photomask, in which a light shielding pattern made of a light shielding film 2 is provided on a transparent substrate 1. FIG. 11B shows the optical intensity amplitude, and FIG. 11C shows the optical intensity distribution. As shown in FIG. 11B, the photomask having this shape produces an optical intensity amplitude having some overlap in the light shielding region. Consequently, as shown in FIG. 11C, the optical intensity distribution is amplified in the light shielding region. This is an effect due to diffracted light from adjacent patterns. This effect deteriorates optical contrast and causes reduced resolution. This makes it very difficult to process a pattern with a size below the wavelength of exposure light.

In this respect, one way of overcoming this limitation is the phase shift technology.

In this technology, a prescribed set of space portions in the transmitting region is provided with an optical path length different from that of the other set of space portions in the transmitting region, thereby shifting the optical phase on the wafer by 180 degrees between the two patterns. This enhances optical contrast on the wafer and achieves significant improvement over the resist resolution obtained by using a conventional photo exposure apparatus.

FIG. 12 shows a cross-sectional shape of the phase shift mask. As shown in the figure, a light shielding pattern made of a light shielding film 2 is provided on a transparent substrate 1. In one of a pair of transmitting regions adjacent to the light shielding pattern, the transparent substrate 1 is trenched to form a recessed region (phase shifter 3). The trenching depth d depends on the wavelength λ of exposure light and the refractive index n of the transparent substrate 1 so that the exposure light transmitted through the phase shifter 3 region has a phase difference of 180 degrees, and is expressed as:
Trenching depth d=λ/2(n−1)

Since the phase shift mask 100 produces 180-degree phase inversion in adjacent transmitting regions of exposure light, the optical intensity distribution in the light shielding regions cancels each other to produce zero optical intensity. Consequently, a dark region occurs in the light shielding region, which enhances optical contrast between the transparent region and the light shielding region. In this manner, the phase shifter 3 shifts the phase of the outgoing exposure light by 180 degrees, thereby canceling the effect of diffracted light in the light shielding region. This enhances optical contrast, and improves the resolution. It is supposed that the resist resolution can be enhanced by using such a phase shift mask for exposure. The foregoing is the principle of enhancing the resolution by the phase shift technology (see, e.g., IEEE Transaction On Electron Devices, Vol. ED-29, No. 12, December 1982, pp. 1828-1836).

The phase shift mask with this structure is disclosed in other literature (see, e.g., Japanese Laid-Open Patent Application H02-140743 (1990)).

However, the following problems occur.

FIG. 13 is a conceptual diagram for illustrating a pattern transferred to a wafer using the phase shift mask in FIG. 12.

In fact, when the phase shift mask 100 with this structure is used to expose a wafer 200 having a si substrate 210 coated with a negative resist film 220, a problem occurs, as shown in FIG. 13, that the line width L₁ of the resist film 220 formed depending on the exposure light transmitted through a trench of the phase shifter 3 is significantly different in dimension from the line width L₂ of the resist film 220 formed depending on the exposure light transmitted through the other transparent region. For this reason, in a typical structure used recently, both of dry etching and wet etching processes are used to form a trench also on the side.

FIG. 14 shows a cross-sectional structure of a phase shift mask having a structure in which a trench is also formed on the side using both of dry etching and wet etching processes.

It is supposed that the structure in which a trench of the phase shifter 3 is also formed on the side can be used to adjust the difference between the processing dimension dependent on the exposure light having a phase of 180 degrees transmitted through the phase shifter 3, that is, the line width L₁ of the resist film 220 on the wafer 200 in FIG. 13, and the processing dimension dependent on the exposure light having a phase of 0 degree transmitted through the other transparent region, that is, the line width L₂ of the resist film 220 on the wafer 200 in FIG. 13 (Japanese Laid-Open Patent Application H08-194303).

FIGS. 15A through 15C show a phase shift mask in FIG. 14 and its optical amplitude and optical intensity distribution.

FIG. 15A shows a phase shift mask in FIG. 14. FIG. 15B shows the optical intensity amplitude, and FIG. 15C shows the optical intensity distribution. As shown in FIG. 15B, since the phase shift mask 100 produces phase inversion in adjacent light transmitting regions, the optical intensity distribution in the light shielding regions cancels each other to produce zero optical intensity as shown in FIG. 15C.

FIG. 16 is a conceptual diagram for illustrating a pattern transferred to a wafer using the phase shift mask in FIG. 14.

When the phase shift mask 100 with this structure is used to expose a wafer 200 having a substrate 210 coated with a resist film 220, the dimensional difference is reduced, as shown in FIG. 16, between the line width L₁ of the resist film 220 formed depending on the exposure light transmitted through a trench of the phase shifter 3 and the line width L₂ of the resist film 220 formed depending on the exposure light transmitted through the other transparent region.

There are other technologies disclosed in the literature. One technology relates to a half-tone phase shift mask with light shielding regions in which a light shielding film having a smaller width than a translucent film (half-tone film) is provided on top of the translucent film. Another technology relates to a half-tone phase shift mask comprising a half-tone film instead of the light shielding film, in which the film thickness of the half-tone film is varied halfway so that adjacent light transmitting regions have a 180-degree phase difference between the opposite sides of the half-tone film (see, e.g., Japanese Laid-Open Patent Applications 2001-22048, 2000-267255, and 2003-121988).

Here, the phase shift mask described above with reference to FIG. 14, in which the sides of the phase shifter 3 are also trenched, has some problems when the light shielding pattern is scaled. This is because, when the size of the light shielding pattern is decreased with scaling, the contact area between the light shielding film and the transparent substrate supporting it decreases. This results in falling down or peeling off of the light shielding pattern.

FIGS. 17A through 17C show the processing size dependence of the light shielding pattern by a conventional phase shift mask.

FIG. 17A schematically shows the positional relationship between the light shielding pattern made of the light shielding film 2 and the trenched portion of the phase shifter 3 in the structure of a phase shift mask when the exposure light has a wavelength of 157 nm, for example. FIG. 17B schematically shows the positional relationship between the light shielding pattern size and the trenched portion of the phase shifter 3 when the light shielding pattern size decreases by a factor of ¾ where the light shielding pattern size of FIG. 17A is assumed to be 1. FIG. 17C schematically shows the positional relationship between the light shielding pattern size and the trenched portion of the phase shifter 3 when the light shielding pattern size decreases by a factor of ½ where the light shielding pattern size of FIG. 17A is assumed to be 1. As shown in FIG. 17, as the size of the light shielding pattern becomes smaller, the opening width of the trenched portion of the phase shifter 3 does not follow the reduction of size of the light shielding pattern. This reduces the contact area with the supporting transparent substrate 1, which results in falling down or peeling off of the light shielding pattern. For example, suppose that the applied exposure light has a wavelength of 157 nm and the numerical aperture (NA) is 0.85. The amount of undercut required to correct the dimensional difference between the line width L1 of the resist pattern transferred to the wafer surface formed depending on the exposure light transmitted through the trench acting as a phase shifter 3, and the line width L2 of the resist pattern transferred to the wafer surface formed depending on the exposure light transmitted through the other transparent region, is 150 nm on the mask (see SPIE2003, 5040-110). It is 30 nm on the wafer for a reduction ratio of 1/5. Assuming a light shielding pattern at the 65-nm level, the area ratio supported by the transparent substrate 1 decreases to about a half. For a light shielding pattern at the 45-nm level, the area ratio supported by the transparent substrate 1 further decreases to ⅓. This results in falling down or peeling off of the light shielding pattern.

### SUMMARY OF THE INVENTION

According to an aspect of the invention, there is provided a phase shift mask comprising: a transparent substrate having two regions that transmit exposure light, the exposure light transmitted through one region having a phase that is inverted in a recessed portion formed in the other region; and a light shielding film that shields the exposure light, the light shielding film being formed on the transparent substrate with a plurality of film thicknesses and having an edge that does not hang over the recessed portion.

The light shielding film may be formed with two film thicknesses, one film thickness being generally ½ of the other film thickness.

The light shielding film may have a portion having an optical density of 3 or greater.

The light shielding film may be formed with two film thicknesses, a portion having a smaller film thickness being provided adjacent to the recessed portion.

The light shielding film may be formed with two film thicknesses using Cr (chromium), one film thickness being 110 nm or greater and the other film thickness being 60 nm or greater.

The light shielding film may be formed between the two regions to have a film thickness that varies at a center portion between the two regions.

The light shielding film may be formed so that the exposure light has a transmissivity of less than 1% also in a portion formed with a smaller film thickness.

According to other aspect of the invention, there is provided a phase shift mask comprising: a transparent substrate having a first region that transmits exposure light without substantially changing its phase and a second region that transmits the exposure light with its phase substantially inverted; and a light shielding film that shields the exposure light, the light shielding film being provided between the first region and the second region on the transparent substrate, and having a portion of a first thickness and a portion of a second thickness that is different from the first thickness.

The second thickness may be generally ½ of the first thickness.

The light shielding film may have a portion having an optical density of 3 or greater.

The light shielding film may be formed from Cr (chromium), and the first thickness may be 110 nm or greater, and the second thickness is 60 nm or greater.

The first thickness may be greater than the second thickness, and the portion of the first thickness may be formed adjacent to the first region.

A boundary between the portion of the first thickness and the portion of the second thickness may be near the center between the first region and the second region.

The exposure light may have a transmissivity of less than 1% both in the portion of the first thickness and the portion of the second thickness.

According to other aspect of the invention, there is provided a method of manufacturing a phase shift mask comprising: a light shielding film forming step of forming a light shielding film that shields exposure light on a transparent substrate; a first light shielding film etching step of selectively etching the light shielding film formed in the light shielding film forming step; a substrate etching step of selectively etching the transparent substrate etched in the first light shielding film etching step and having an exposed surface of the transparent substrate; and a second light shielding film etching step of selectively etching the light shielding film not etched in the first light shielding film so that the light shielding film has a plurality of film thicknesses.

In the substrate etching step, an anisotropic etching method may be used.

In the substrate etching step, selective etching may be performed so that etched and unetched regions are alternately arranged with the light shielding film interposed therebetween.

In the second light shielding film etching step, a portion nearer to the region etched in the substrate etching step may be etched.

In the second light shielding film etching step, etching ma y be performed so that the etched portion of the light shielding film has a film thickness reduced to generally a half.

The light shielding film may be formed from Cr (chromium), and in the second light shielding film etching step, the light shielding film that has been selectively etched may have a thickness of 60 nm or greater, and the light shielding film that has not been selectively etched may have a thickness of 110 nm or greater.

### BRIEF DESCRIPTION OF THE DRAWINGS

The present invention will be understood more fully from the detailed description given here below and from the accompanying drawings of the embodiments of the invention. However, the drawings are not intended to imply limitation of the invention to a specific embodiment, but are for explanation and understanding only.

In the drawings:

FIG. 1 illustrates a cross-sectional configuration of a phase shift mask in a first embodiment;

FIG. 2 shows the relationship between the line width of a resist pattern obtained when transferred to a wafer and the film thickness of the light shielding film;

FIG. 3 is a flow chart showing a relevant part of a method of manufacturing the phase shift mask 100 in FIG. 1;

FIGS. 4A through 4F are process cross-sectional views showing a process carried out corresponding to the flow chart of FIG. 3;

FIG. 5 is a conceptual diagram of an apparatus for etching by the reactive ion etching method;

FIGS. 6G through 6L are process cross-sectional views showing a process carried out corresponding to the flow chart of FIG. 3;

FIG. 7 is a conceptual diagram for illustrating the configuration of a projection exposure apparatus;

FIGS. 8A through 8C show a phase shift mask and its optical amplitude and optical intensity distribution according to the present embodiment;

FIGS. 9A and 9B are conceptual diagrams for illustrating a pattern transferred to a wafer using the phase shift mask according to the present embodiment;

FIGS. 10A through 10C show the processing size dependence of the light shielding pattern by a phase shift mask according to the present embodiment;

FIGS. 11A through 11C show a conventional photomask and its optical amplitude and optical intensity distribution;

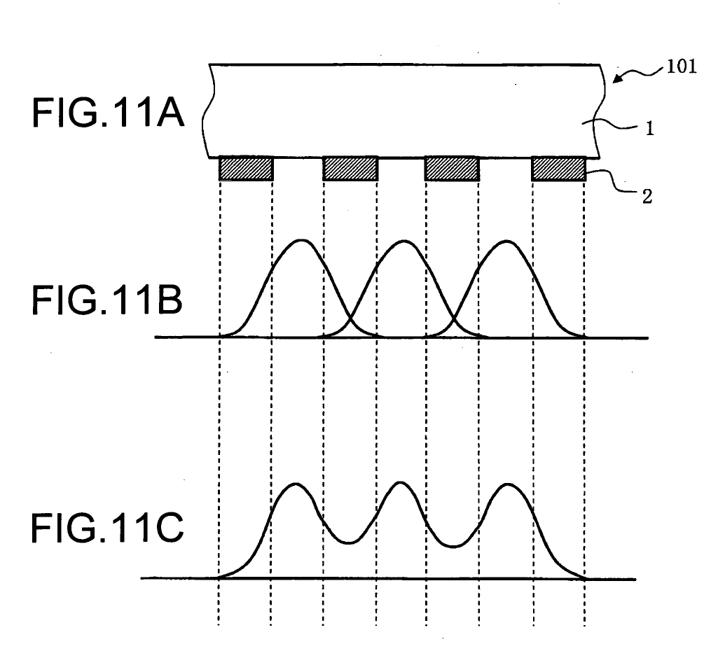

FIG. 12 shows a cross-sectional shape of the phase shift mask;

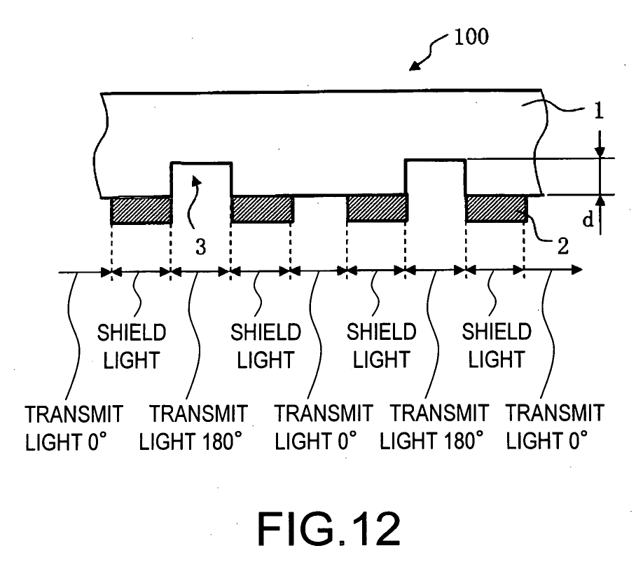

FIG. 13 is a conceptual diagram for illustrating a pattern transferred to a wafer using the phase shift mask in FIG. 12;

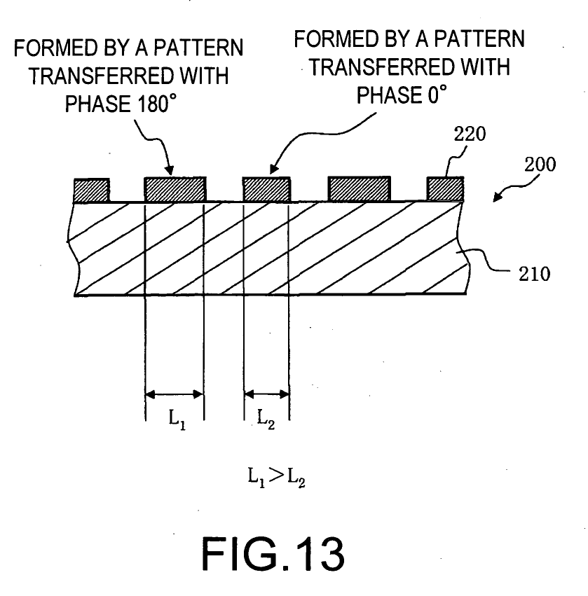

FIG. 14 shows a cross-sectional structure of a phase shift mask having a structure in which a trench is also formed on the side using both of dry etching and wet etching processes;

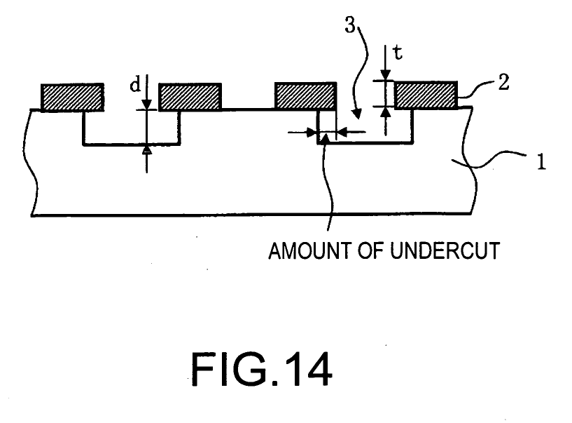

FIGS. 15A through 15C show a phase shift mask in FIG. 14 and its optical amplitude and optical intensity distribution;

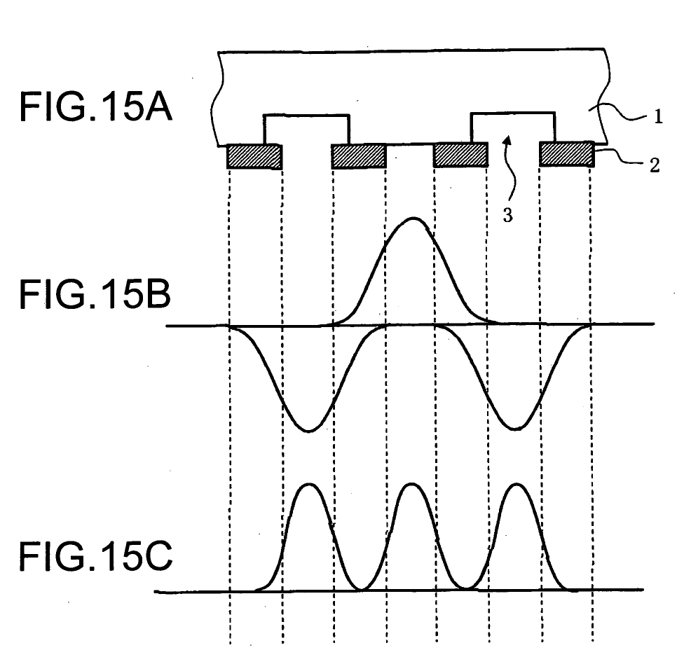

FIG. 16 is a conceptual diagram for illustrating a pattern transferred to a wafer using the phase shift mask in FIG. 14; and

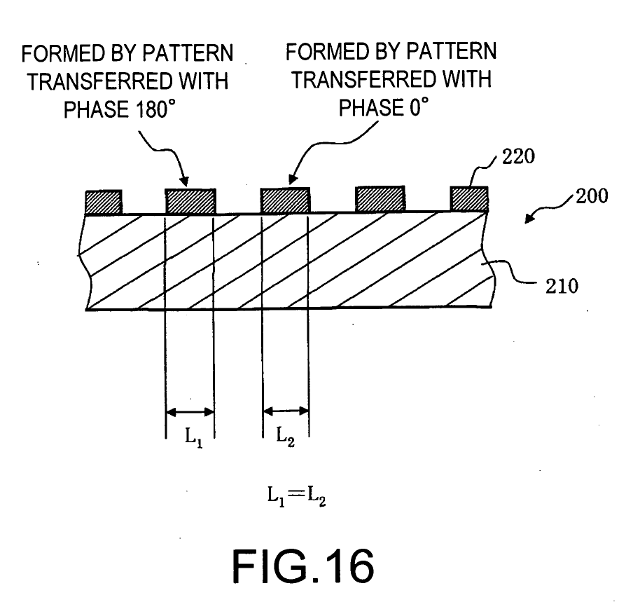

FIGS. 17A through 17C show the processing size dependence of the light shielding pattern by a conventional phase shift mask.

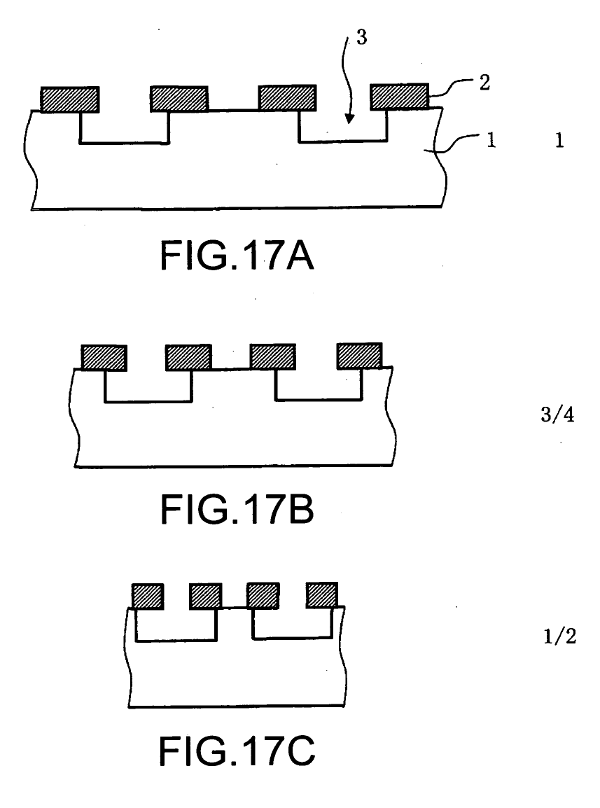

### DETAILED DESCRIPTION

In the following embodiment, a phase shift mask has a structure of a trenched transparent substrate. In the structure of the phase shift mask now described, the light shielding film pattern on the transparent substrate has the capability of correcting the resist pattern width dimension on the wafer, rather than correcting the resist pattern width dimension on the wafer using the trenched shape in the direction into the side of the transparent substrate, in order to avoid reduction of the area where the transparent substrate supports the light shielding pattern. To achieve this structure, the light shielding film has a structure such that the light shielding film pattern on the transparent substrate has two, or three or more levels of film thickness. This structure can be applied to avoid reduction of the area where the transparent substrate supports the light shielding pattern, and thus avoid the phenomenon of falling down and peeling off of the light shielding pattern. It can also achieve the effect that the optical intensity profile having a phase of 0 degree transmitted through the transparent region can be identical to the optical intensity profile having a phase of 180 degrees. The present embodiment is described with reference to a phase shift mask characterized by the above mask structure and a method of manufacturing the same, and a method of exposing the same.

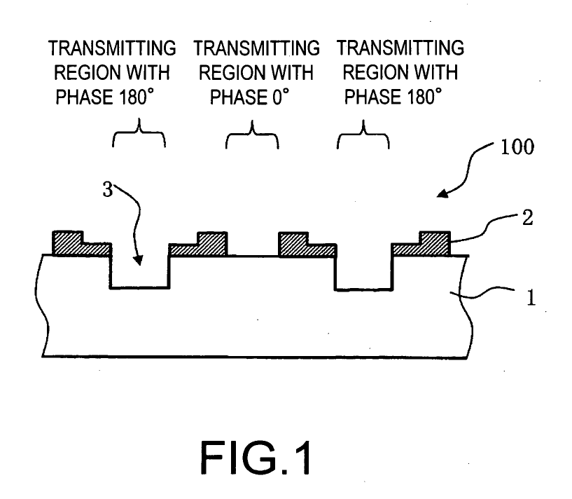

FIG. 1 illustrates a cross-sectional configuration of a phase shift mask in a first embodiment.

In FIG. 1, a phase shift mask 100 comprises a transparent substrate 1 and a light shielding film 2.

The transparent substrate 1 has phase shifters 3 formed as recessed portions. Having the phase shifters 3 implies having two regions that transmit exposure light with a phase of 0 and 180 degrees, respectively. One region remains to be the original surface of the transparent substrate not recessed. The other region has the phase shifters 3 formed therein. The phase shifter 3 can invert the phase of the exposure light transmitted through one of the regions corresponding to the transparent substrate surface not recessed.

The light shielding film 2 is formed with a plurality of film thicknesses on the transparent substrate 1 so that its edge does not hang over the recessed portion acting as the phase shifter 3. The light shielding film 2 shields the exposure light. Since it is formed on the transparent substrate 1 so that its edge does not hang over the recessed portion acting as the phase shifter 3, it is entirely supported by the transparent substrate 1, thus avoiding falling down and peeling off of the light shielding pattern of the light shielding film 2.

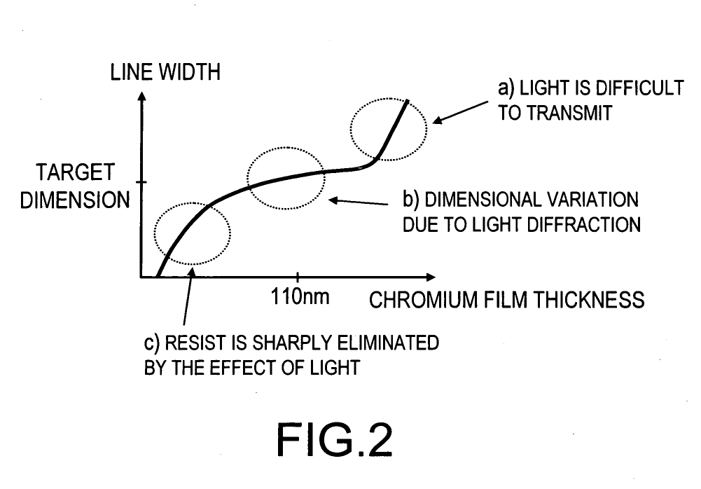

FIG. 2 shows the relationship between the line width of a resist pattern obtained when transferred to a wafer and the film thickness of the light shielding film.

The line width of the resist pattern (space width of the resist) obtained when transferred to the wafer is related to the film thickness of the light shielding film (e.g., chromium film thickness in this case) as shown in FIG. 2. Region (a) is a region where light from the transmitting region is difficult to transmit, and thus the resist is not resolved. Region (b) is a region where light from the transmitting region can be passed, which causes dimensional variation due to light diffraction. Region (c) is a region where the resist is sharply eliminated by the effect of light transmission and diffraction.

In the region (b) where light from the transmitting region can be passed and the optical density is 3 or greater, the line width of the resist is subjected to dimensional variation due to diffraction of light from the neighboring transmitting regions. A light shielding film with smaller thickness enhances scattered light, which results in greater effect due to light diffraction, and hence reduces the line width of the resist. The phase shift mask according to the present embodiment is an application of this phenomenon. Consequently, the film thickness can be reduced in the transmitting region where the line width of the resist pattern (space width of the resist) is greater when transferred to the wafer. This can increase the effect due to light diffraction from the film portion having smaller thickness when transferred to the wafer, which can reduce the line width of the resist pattern nearer to the transmitting region where the line width of the resist pattern is greater when transferred to the wafer. It is thus preferred that, also in order to avoid influence exerted between the normal transmitting portion that is not recessed and the shifter transmitting portion that is recessed, the light shielding film 2 in FIG. 1 be formed between the two regions so that the film thickness varies at the central portion between the two regions.

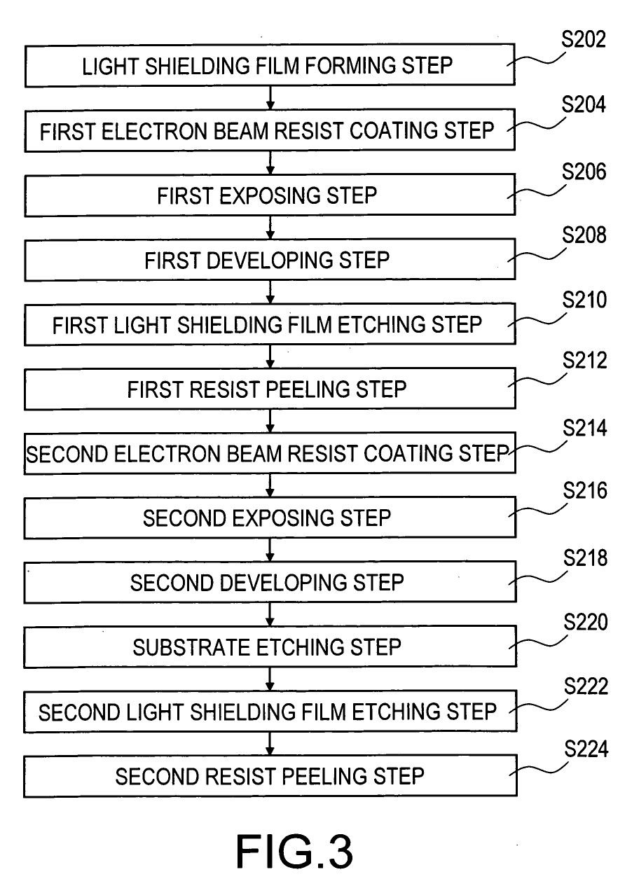

FIG. 3 is a flow chart showing a relevant part of a method of manufacturing the phase shift mask 100 in FIG. 1.

In FIG. 3, the present embodiment carries out a series of steps comprising a light shielding film forming step (S202) of forming a light shielding film 2, a first electron beam resist coating step (S204) of coating electron beam resist, a first exposing step (S206) of exposing the electron beam resist, a first developing step (S208) of developing the exposed electron beam resist, a first light shielding film etching step (S210) of etching the light shielding film 2, a first resist peeling step (S212) of peeling the electron beam resist, a second electron beam resist coating step (S214) of coating electron beam resist, a second exposing step (S216) of exposing the electron beam resist, a second developing step (S218) of developing the exposed electron beam resist, a substrate etching step (S220) of etching the transparent substrate 1, a second light shielding film etching step (S222) of etching the light shielding film 2, and a second resist peeling step (S224) of peeling the electron beam resist.

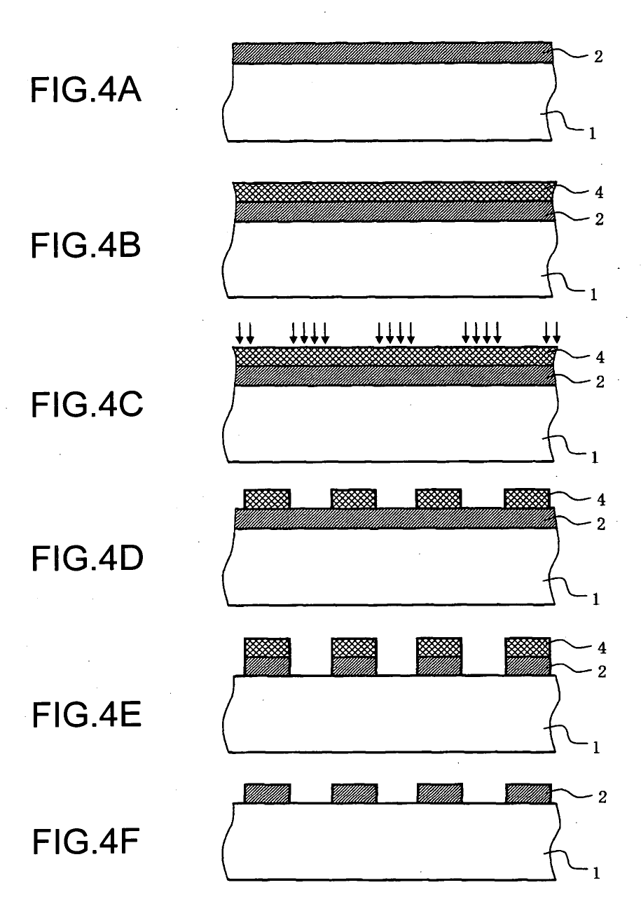

FIG. 4 is a process cross-sectional view showing a process carried out corresponding to the flow chart of FIG. 3.

FIGS. 4A through 4F show the steps in FIG. 3 from the light shielding film forming step (S202) to the first resist peeling step (S212). The subsequent steps will be described later.

In FIG. 4A, which illustrates the light shielding film forming step, a light shielding film 2 for shielding exposure light is formed on the transparent substrate 1. The transparent substrate 1 is made of material having a transmissivity as high as 80% or greater at the wavelength of the applied exposure light. For example, modified quartz glass is effective, which has a transmissivity of 85% or greater at wavelengths of the exposure light above 157 nm. The light shielding film 2 is made of material having low transmissivity at the wavelength of the applied exposure light. For example, Cr (chromium) is desirable, which has a transmissivity of 0.5% or less for light with a wavelength of 157 nm or greater. Alternatively, the material may be iron oxide, nickel, silicon, germanium oxide, or zirconium oxide. The light shielding film 2 may be made of material having a transmissivity of less than 1%. Using Cr for the material of the light shielding film 2 makes etching easier than using nickel or other material that is difficult to etch. It is desirable that the film thickness to be formed (target film thickness) be, for example, 110 nm or greater for Cr, which can achieve the optical density of 3 or greater. Also for other materials, film thickness that can achieve the optical density of 3 or greater is desirable. For the film forming method, sputtering or vacuum vapor deposition may be used, although any other method can also be used.

In FIG. 4B, which illustrates the first electron beam resist coating step, on the blank mask having the light shielding film 2 formed on the transparent substrate 1, the formed light shielding film 2 is coated with electron beam resist to form a resist film 4. The electron beam resist is coated by the spin-coating or other method. Use of electron beam resist enables processing of fine patterns. While electron beam resist is used here, other resist films having photosensitivity to ultraviolet or other light may also be used.

In FIG. 4C, which illustrates the first exposing step, the coated electron beam resist is exposed. The exposure is carried out by irradiating selective regions of the resist film 4 with electron beam using an electron beam imaging apparatus. The light shielding film 2 is exposed, and the region to be etched is subjected to electron beam imaging. The amount of electric charge required for the electron beam resist to be resolved is specified to irradiate electron beam. In the electron beam imaging step, when the electron beam resist is positive resist, the regions where the light shielding film 2 will remain may be left unimaged.

In FIG. 4D, which illustrates the first developing step, the exposed electron beam resist is developed. The development is carried out by immersion in developing solution. Development causes the resist film 4 to be selectively patterned, distinguishing the resist region and the non-resist region. In such a developing step for electron beam resist, when positive resist is used for the electron beam resist, the electron beam resist in the region irradiated with electron beam dissolves in developing solution to expose the light shielding film 2. In the region not irradiated with electron beam, the electron beam resist does not dissolve in developing solution, and thus the pattern of the electron beam resist is left.

In FIG. 4E, which illustrates the first light shielding film etching step, the light shielding film 2 is selectively etched to the surface of the transparent substrate 1. For the etching method, it is desired to use an anisotropic etching method. Use of the anisotropic etching method enables etching vertical to the substrate surface. For example, when dry etching is performed on the light shielding film 2, the parallel-plate reactive ion etching (RIE) method is applied. For example, when the light shielding film is made of Cr, etching gas containing CCl₄ (tetrachloromethane) and O₂ (oxygen), or CH₂Cl₂ (dichloromethane) and O₂ may be used with the flow ratio adjusted to 1:3. At the time of etching, the etching selection ratio relative to the transparent substrate 1 must be sufficiently high. The electron beam resist used for the material of the resist film 4 serves as a protection film against etching. As a result, only the light shielding film in the region not covered with electron beam resist is removed, and the transparent substrate 1 is partially exposed. When the Cr film is subjected to dry etching using CCl₄ and O₂, or CH₂Cl₂ and O₂ with the flow ratio adjusted to 1:3, the electron beam resist is sufficiently resistive to etching. As additive gas, any one of Ar (argon), N₂ (nitrogen), and HCl (hydrochloric acid) may be mixed. This mixing can enhance homogeneity for different types of patterns. For example, mixing HCl can enhance homogeneity of the etching rate.

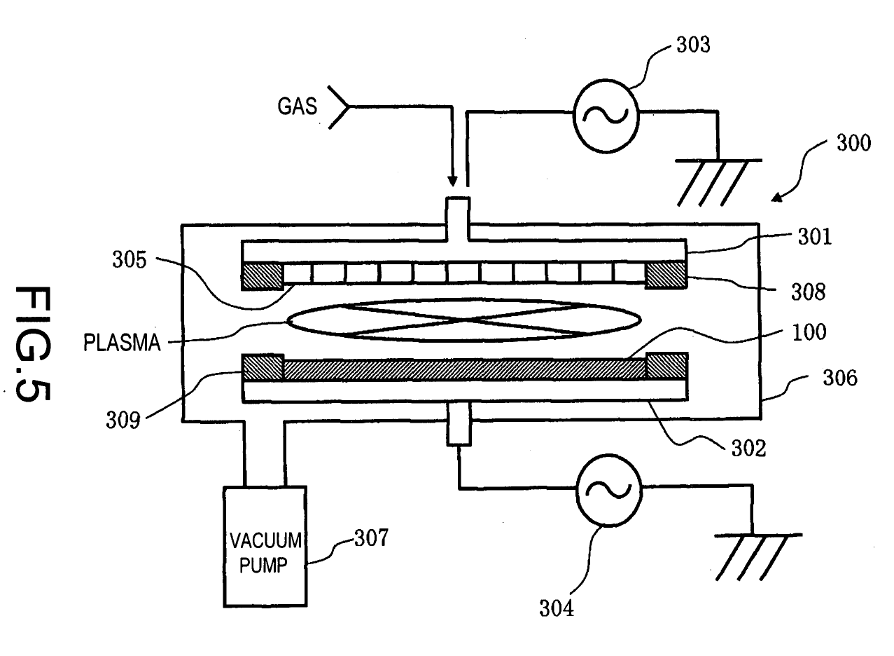

FIG. 5 is a conceptual diagram of an apparatus for etching by the reactive ion etching method.

In FIG. 5, an apparatus 300 includes a chamber 306 in which the phase shift mask 100 is placed on a lower electrode 302. The phase shift mask 100 is placed inside the lower ring 309. Mixture gas acting as etching gas is supplied into the chamber 306 from a gas ejection plate 305 inside an upper ring 308. A vacuum pump 307 evacuates the chamber 306 to a predetermined chamber inner pressure. An upper RF power supply 303 acting as a radio-frequency power supply is used to generate plasma between an upper electrode 301 and a lower electrode 302 inside the chamber 306. On the other hand, a lower RF power supply 304 is used to control ion energy. This type of etching apparatus is desirable, which has a RF power supply for generating plasma separated from a RF power supply for controlling ion energy. In parallel-plate RIE in which the RF power supply for generating plasma is not separated from the RF power supply for controlling ion energy (the RF power supply is provided only on the side where the phase shift mask is placed), increase of RF power for increasing the etch rate also increases ion energy, which makes it difficult to provide selectivity. On the contrary, in an apparatus having separate power supplies, it is easy to provide selectivity by increasing the RF power for plasma generation while holding down the RF power for ion energy control.

Here, a desirable etching condition for the first light shielding film etching step is, for example, a plasma power of about 200 W, and a bias voltage of about 100 V. In addition, the vacuum pump 307 is used to evacuate the chamber to decrease the chamber inner pressure below 13.3 Pa (0.1 Torr). A lower chamber inner pressure is more desirable.

In FIG. 4F, which illustrates the first resist peeling step, the electron beam resist is peeled off. Preferred peeling solution for the resist film 4 may be a mixed solution containing sulfuric acid and hydrogen peroxide solution with a ratio of 3:1. In this respect, the peeling resistance relative to the exposed transparent substrate 1 must be sufficiently high. The peeling is followed by washing, although not shown.

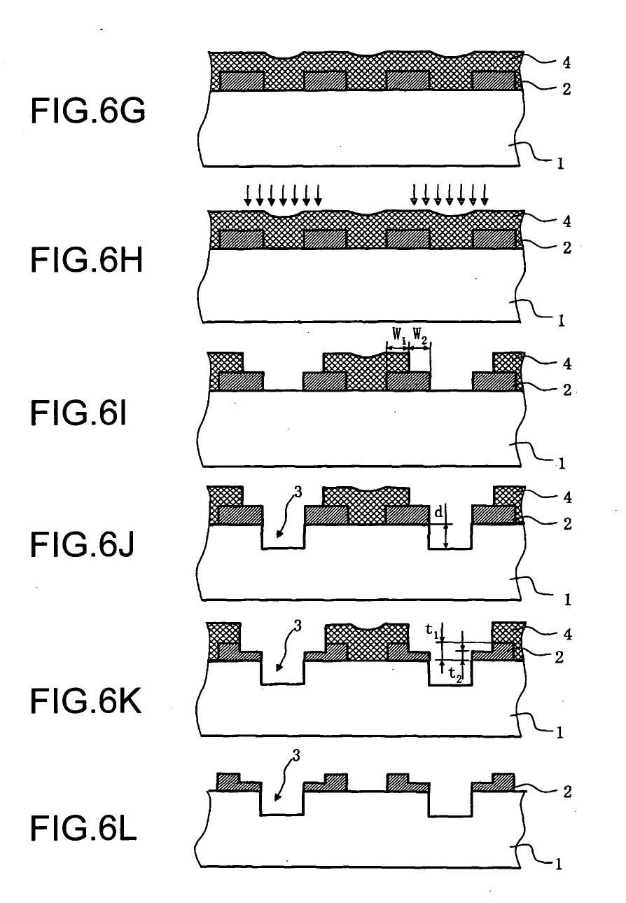

FIGS. 6G through 6L are process cross-sectional views showing a process carried out corresponding to the flow chart of FIG. 3.

FIGS. 6G through 6L show the steps in FIG. 3 from the second electron beam resist coating step (S214) to the second resist peeling step (S224).

In FIG. 6G, which illustrates the second electron beam resist coating step, the transparent substrate 1 exposed by etching the light shielding film 2, and the light shielding film 2 that has not been etched, are coated with electron beam resist to form a resist film 4 once again. As described above, the electron beam resist is coated by the spin-coating or other method. Use of electron beam resist enables processing of fine patterns. While electron beam resist is used here, other resist films having photosensitivity to ultraviolet or other light may also be used.

In FIG. 6H, which illustrates the second exposing step, the coated electron beam resist is exposed. The exposure is carried out by irradiating selective regions of the resist film 4 with an electron beam using an electron beam imaging apparatus. The transparent substrate 1 and the light shielding film 2 are selectively exposed, and the region to be etched is subjected to electron beam imaging. The amount of electric charge required for the electron beam resist to be resolved is specified to irradiate electron beam. In the electron beam imaging step, when the electron beam resist is positive resist, the regions where the light shielding film 2 will ultimately remain may be left unimaged.

In FIG. 6I, which illustrates the second developing step, the exposed electron beam resist is developed. The development is carried out by immersion in developing solution. Development causes the resist film 4 to be selectively patterned, distinguishing the resist region and the non-resist region. In such a developing step for electron beam resist, when positive resist is used for the electron beam resist, the electron beam resist in the region irradiated with electron beam dissolves in developing solution to expose the transparent substrate 1 and the light shielding film 2. In the region not irradiated with electron beam, the electron beam resist does not dissolve in developing solution, and thus the pattern of the electron beam resist is left. It is desirable to pattern the light shielding film 2 so that the width W1 hidden behind the resist film 4 is equal to the exposed width W2. By this equal-width patterning, the light shielding film 2 can be formed to vary its film thickness at the central portion. When transferred to the wafer, the influence of the light shielding film, which is formed with a plurality of film thicknesses that vary at the central portion, can thus be limited to a desired one of the two transmitting regions, and prevented from acting on the other undesired one.

In FIG. 6J, which illustrates the substrate etching step, the transparent substrate 1, which has exposed its transparent substrate surface, is selectively etched. In the substrate etching step, selective etching is performed so that etched and unetched regions are alternately arranged with the light shielding film 2 interposed therebetween. In the etched region, a phase shifter 3 is formed that is 180 degrees out of phase relative to the unetched region. The trenching depth d for the etched region depends on the wavelength λ of exposure light and the refractive index n of the transparent substrate 1, and is expressed as:
Trenching depth d=λ/2(n−1)

By performing selective etching so that etched and unetched regions are alternately arranged with the light shielding film 2 interposed therebetween, the phase of light on the wafer can be shifted by 180 degrees between the two patterns. This enhances optical contrast on the wafer and achieves significant improvement over the resist resolution obtained by using a conventional photo exposure apparatus. This can in turn be used to process a pattern size below the wavelength of exposure light.

For the etching method, it is desired to use an anisotropic etching method. Use of the anisotropic etching method enables etching vertical to the substrate surface. Vertical etching can avoid trenching the transparent substrate 1 under the light shielding film 2. In other words, the side of the phase shifter 3 can be prevented from being trenched. Falling down and peeling off of the light shielding pattern can be avoided even when the light shielding pattern has a smaller size because the side of the phase shifter 3 can be prevented from being trenched. For example, when dry etching is performed on the transparent substrate 1, the parallel-plate reactive ion etching method is applied using the reactive ion etching apparatus shown in FIG. 5. For example, when the transparent substrate 1 is made of quartz glass, etching gas containing CF₄ (tetrafluoromethane) and O₂ may be used with the flow ratio adjusted to 20:1. At the time of etching, the resist film 4 serves as a protection film against etching. As a result, the quartz glass in the region not covered with the resist film 4 is etched. When quartz glass is subjected to dry etching using CF₄ and O₂ with the flow ratio adjusted to 20:1, the electron beam resist is sufficiently resistive to etching.

Here, a desirable etching condition for the substrate etching step is, for example, a plasma power of about 100 W, and a bias voltage of about 80 V. This increases the etching rate, while preventing glass fragments of the etched transparent substrate 1 from falling on the resist. In addition, the vacuum pump 307 is used to evacuate the chamber to decrease the chamber inner pressure below 13.3 Pa (0.1 Torr). A lower chamber inner pressure is more desirable.

In FIG. 6K, which illustrates the second light shielding film etching step, the light shielding film 2 is selectively etched so that the light shielding film 2 that was not etched in the first light shielding film etching step has a plurality of film thicknesses. Here, etching is performed on the portion nearer to the region that was etched in the substrate etching step is etched. Scattered light is thus enhanced in the portion nearer to the region etched in the substrate etching step, which results in greater effect due to light diffraction. As a result, the film thickness of the light shielding film can be reduced in the region where the line width of the resist pattern is greater when transferred to the wafer. For example, when the light shielding film 2 is made of Cr and formed with two film thicknesses, the light shielding film 2 that was formed with a film thickness of t₁ being 110 nm or greater in the light shielding film forming step is selectively etched to form a film thickness of t₂ being 60 nm or greater. By setting the film thickness t₂ on the thinner side to 60 nm, pinhole defects can be avoided. When the light shielding film 2 is formed with two film thicknesses, it is desirable that the film thickness t₂ of the etched, thinned film is generally ½ of the film thickness t₁ of the initially formed film. By forming the film with one film thickness approximating to ½ of the other film thickness, its optical contrast can be enhanced when transferred to the wafer. However, the invention is not limited thereto. As described above, the line width of the resist pattern obtained when transferred to the wafer depends on the film thickness of the light shielding film 2. Consequently, the film thickness may be adjusted through the amount of etching in accordance with the dimensional difference between the line width L₁ of the resist pattern formed depending on the exposure light transmitted through a trench acting as the phase shifter 3 and the line width L₂ of the resist pattern formed depending on the exposure light transmitted through the other transparent region, thereby keeping the dimensional difference as small as possible. In addition, it is desirable that the light shielding film 2 be formed so that the transmissivity of the exposure light is less than 1% even in the portion having smaller film thickness. This is because, at a transmissivity of 1% or greater, the phase effect of light must be taken into consideration.

When thinning is performed on the light shielding film 2, it is desirable that the parallel-plate reactive ion etching (RIE) method be applied using the reactive ion etching apparatus shown in FIG. 5. For example, when the light shielding film is made of Cr, etching gas containing CCl₄ and O₂, or CH₂Cl₂ and O₂ may be used with the flow ratio adjusted to 1:3. At the time of thinning the light shielding film 2, the etching selection ratio relative to the transparent substrate 1 must be sufficiently high. The resist film 4 of electron beam resist serves as a protection film against etching. As a result, only the light shielding film 2 in the region not covered with the resist film 4 is removed by a predetermined amount of etching. When the Cr film is subjected to thinning using CCl₄ and O₂, or CH₂Cl₂ and O₂ with the flow ratio adjusted to 1:3, the electron beam resist is sufficiently resistive to etching. As additive gas, any one of Ar, N₂, and HCl may be mixed. This mixing can enhance homogeneity for different types of patterns. For example, mixing HCl can enhance homogeneity of the etching rate, as described above.

Here, a desirable etching condition for the second light shielding film etching step is, for example, a plasma power of about 50 W, and a bias voltage of about 40 V. As compared to the first light shielding film etching step, lower power and longer etching time are desirable to facilitate controlling the amount of etching. The film of the thinner portion can be formed with precise thickness by holding down the etching rate. In addition, the vacuum pump 307 is used to evacuate the chamber to decrease the chamber inner pressure below 13.3 Pa (0.1 Torr). A lower chamber inner pressure is more desirable.

In FIG. 6L, which illustrates the second resist peeling step, the electron beam resist is peeled ff. Preferred peeling solution for the resist film 4 may be a mixed solution containing sulfuric acid and hydrogen peroxide solution with a ratio of 3:1. In this respect, the peeling resistance relative to the exposed transparent substrate 1 and light shielding film 2 must be sufficiently high. Peeling is followed by washing, although not shown.

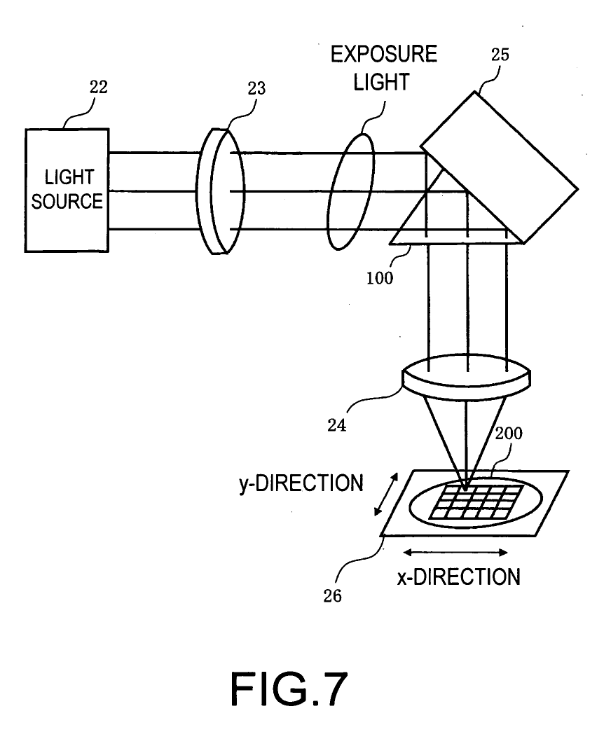

FIG. 7 is a conceptual diagram for illustrating the configuration of a projection exposure apparatus.

The phase shift mask 100 manufactured by the manufacturing method described above in the present embodiment is placed in the projection exposure apparatus. FIG. 7 shows the concept of photolithography exposure technology according to the present embodiment. As shown in FIG. 7, exposure light emitted from an exposure light source 22 is transmitted through a lens 23, reflected on a mirror 25, transmitted through the phase shift mask 100, and incident on an exposure projection system lens 24. The light is then converged inside the exposure projection system lens 24 and irradiated to photoresist on the wafer 200.

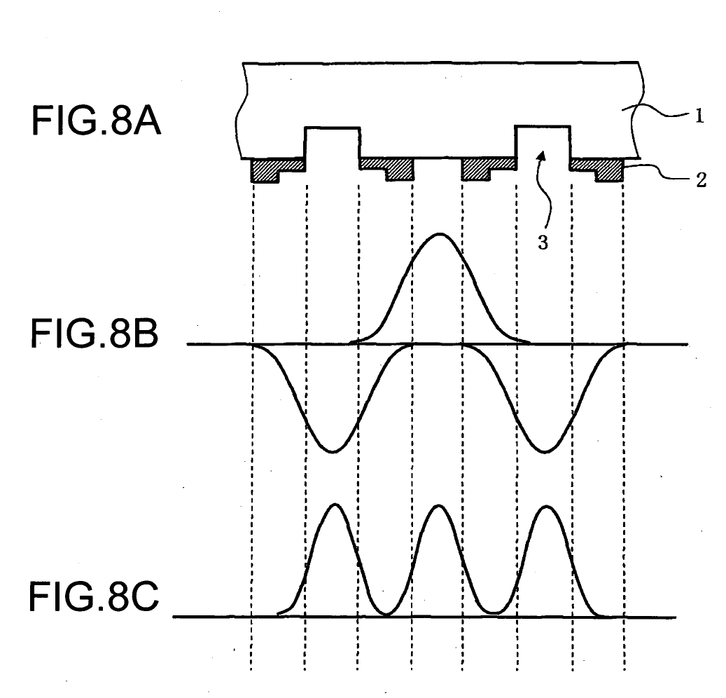

FIGS. 8A through 8C show a phase shift mask and its optical amplitude and optical intensity distribution according to the present embodiment.

FIG. 8A shows a phase shift mask 100 in the present embodiment. FIG. 8B shows the optical intensity amplitude, and FIG. 8C shows the optical intensity distribution. As shown in FIG. 8B, since the phase shift mask 100 produces phase inversion in adjacent light transmitting regions, the optical intensity distribution in the light shielding regions cancels each other to produce zero optical intensity as shown in FIG. 8C. Consequently, a dark region is produced in the light shielding region, which enhances optical contrast. In this manner, also with respect to the novel phase shift mask 100, the phase shifter 3 shifts the phase of the outgoing exposure light by 180 degrees, thereby canceling the effect of diffracted light in the light shielding pattern region. This enhances optical contrast, and hence the resolution.

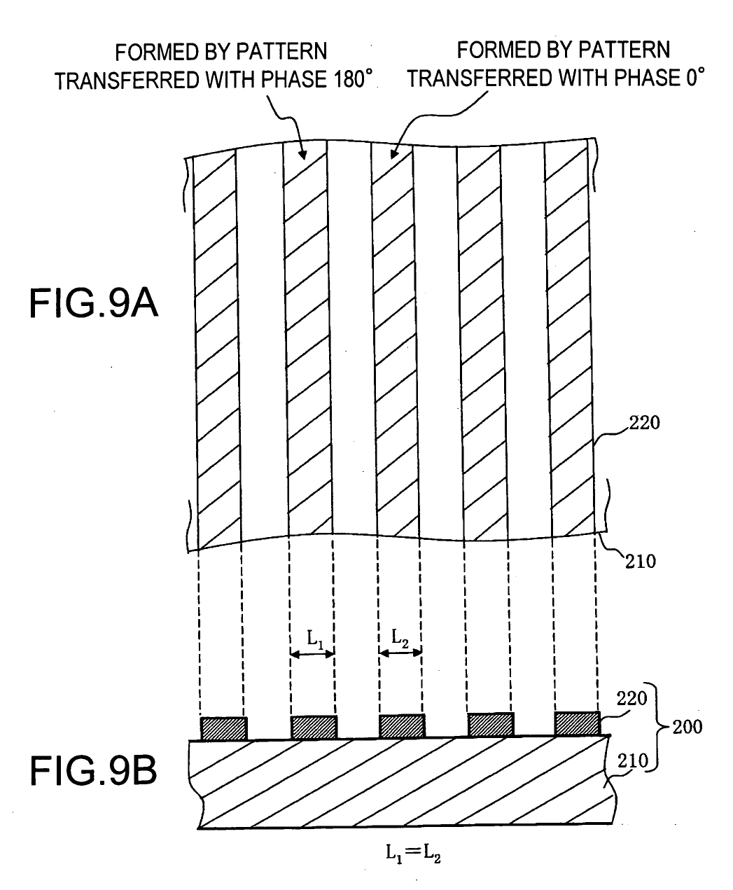

FIGS. 9A and 9B are conceptual diagrams for illustrating a pattern transferred to a wafer using the phase shift mask according to the present embodiment.

FIG. 9A shows a conceptual diagram in which the pattern transferred to the wafer is viewed from above the wafer. FIG. 9B shows a conceptual diagram in which the pattern transferred to the wafer is viewed in the cross section of the wafer. When the phase shift mask 100 with this structure is used to expose a wafer 200 having a substrate 210 coated with a resist film 220, the dimensional difference is reduced, as shown in FIGS. 9A and 9B, between the line width L₁ of the resist film 220 formed depending on the exposure light transmitted through a trench of the phase shifter 3 and the line width L₂ of the resist film 220 formed depending on the exposure light transmitted through the other transparent region, because the light shielding film 2 nearer to the phase shifter 3 is subjected to thinning to enhance scattered light.

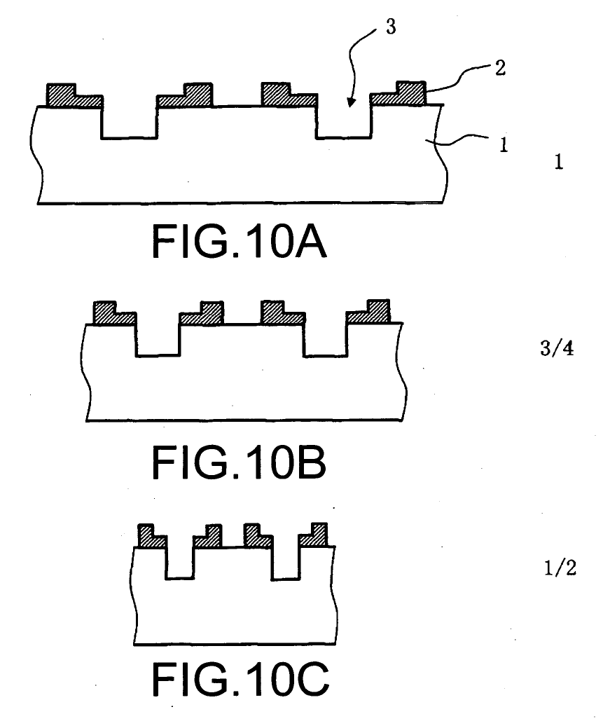

FIGS. 10A through 10C show the processing size dependence of the light shielding pattern by a phase shift mask according to the present embodiment.

FIG. 10A schematically shows the positional relationship between the light shielding pattern made of the light shielding film 2 and the trenched portion of the phase shifter 3 in the structure of a phase shift mask when the exposure light has a wavelength of 157 nm, for example. FIG. 10B schematically shows the positional relationship between the light shielding pattern size and the trenched portion of the phase shifter 3 when the light shielding pattern size decreases by a factor of ¾ where the light shielding pattern size of FIG. 10A is assumed to be 1. FIG. 10C schematically shows the positional relationship between the light shielding pattern size and the trenched portion of the phase shifter 3 when the light shielding pattern size decreases by a factor of ½ where the light shielding pattern size of FIG. 10A is assumed to be 1. As shown in FIG. 10, even when the size of the light shielding pattern gradually becomes smaller, the contact area with the supporting transparent substrate is not reduced, and does not result in falling down or peeling off of the light shielding pattern. For example, suppose that the applied exposure light has a wavelength of 157 nm, the numerical aperture (NA) is 0.85, and the reduction ratio is 1/5. The amount of undercut conventionally required to correct the dimensional difference was 150 nm on the mask (see SPIE2003, 5040-110), and 30 nm on the wafer. However, according to the present embodiment, in a light shielding pattern at the 65-nm level, and further in a light shielding pattern at the 45-nm level, the transparent substrate 1 completely supports the light shielding film 2 acting as a light shielding pattern, and thus avoids any falling down or peeling off of the light shielding pattern.

As described above, in the present embodiment, the phase shift mask 100 has a structure such that the light shielding film pattern on the transparent substrate has the capability of correcting the dimension on the wafer 200, rather than correcting the dimension on the wafer 200 using the trenched shape of the transparent substrate 1, in order to avoid reduction of the area where the transparent substrate 1 supports the light shielding pattern. In order to provide this capability to the light shielding film 2, the light shielding film has a structure such that the light shielding film pattern on the transparent substrate has two levels of film thickness. This structure can be applied to avoid reduction of the area where the transparent substrate 1 supports the light shielding film pattern, and thus avoid the phenomenon of falling down and peeling off of the light shielding film pattern. It can also achieve the effect that the optical intensity profile having a phase of 0 degree transmitted through the transparent region can be made identical to the optical intensity profile having a phase of 180 degrees. In addition, since the light shielding pattern has two levels of film thickness, it can adjust the difference between the processing dimension dependent on the exposure light having a phase of 180 degrees transmitted through the phase shifter 3 and the processing dimension dependent on the exposure light having a phase of 0 degree transmitted through the other transparent region. Here, while the light shielding pattern has two levels of film thickness in the present embodiment, it may have three or more levels. A greater number of levels involve a greater number of steps in manufacturing the mask. However, more precise control on the line width can be achieved according to the type of patterns.

As described above, without providing any trenches on the side of the trenched portion of the phase shifter, the phase shift mask according to the present embodiment can be applied to obtain a pattern similar to that obtained by a conventional phase shift mask, which requires trenches also on the side of the trenched portion of the phase shifter. Moreover, the phase shift mask with this structure can be applied to form a finer light shielding pattern on the mask. As a result, a finer resist pattern can be formed also in the resist pattern on the wafer.

Here, the substrate 210 may have various semiconductor devices and structures, not shown. In addition, the size and number of the light shielding films 2 and the phase shifters 3 may be appropriately selected as required in the semiconductor integrated circuit or various semiconductor devices.

Any method of manufacturing a photomask, including any phase shift mask that comprises the elements of the invention and that may be appropriately modified by those skilled in the art, is encompassed within the scope of the invention.

For convenience of description, conventional techniques used in the semiconductor industry such as cleaning before and after a process are not described. However, it is to be understood that such techniques are included.

While the present invention has been disclosed in terms of the embodiment in order to facilitate better understanding thereof, it should be appreciated that the invention can be embodied in various ways without departing from the principle of the invention. Therefore, the invention should be understood to include all possible embodiments and modification to the shown embodiments which can be embodied without departing from the principle of the invention as set forth in the appended claims.

1. A phase shift mask comprising:
a transparent substrate having two regions that transmit exposure light, the exposure light transmitted through one region having a phase that is inverted in a recessed portion formed in the other region; and
a light shielding film that shields the exposure light, the light shielding film being formed on the transparent substrate with a plurality of film thicknesses and having an edge that does not hang over the recessed portion.

2. The phase shift mask as claimed in claim 1, wherein the light shielding film is formed with two film thicknesses, one film thickness being generally ½ of the other film thickness.

3. The phase shift mask as claimed in claim 1, wherein the light shielding film has a portion having an optical density of 3 or greater.

4. The phase shift mask as claimed in claim 1, wherein the light shielding film is formed with two film thicknesses, a portion having a smaller film thickness being provided adjacent to the recessed portion

5. The phase shift mask as claimed in claim 1, wherein the light shielding film is formed with two film thicknesses using Cr (chromium), one film thickness being 110 nm or greater and the other film thickness being 60 nm or greater.

6. The phase shift mask as claimed in claim 1, wherein the light shielding film is formed between the two regions to have a film thickness that varies at a center portion between the two regions.

7. The phase shift mask as claimed in claim 1, wherein the light shielding film is formed so that the exposure light has a transmissivity of less than 1% also in a portion formed with a smaller film thickness.

8. A phase shift mask comprising:
a transparent substrate having a first region that transmits exposure light without substantially changing its phase and a second region that transmits the exposure light with its phase substantially inverted; and
a light shielding film that shields the exposure light, the light shielding film being provided between the first region and the second region on the transparent substrate, and having a portion of a first thickness and a portion of a second thickness that is different from the first thickness.

9. The phase shift mask as claimed in claim 8, wherein the second thickness is generally ½ of the first thickness.

10. The phase shift mask as claimed in claim 8, wherein the light shielding film has a portion having an optical density of 3 or greater.

11. The phase shift mask as claimed in claim 8, wherein the light shielding film is formed from Cr (chromium), and the first thickness is 110 nm or greater, and the second thickness is 60 nm or greater.

12. The phase shift mask as claimed in claim 8, wherein the first thickness is greater than the second thickness, and the portion of the first thickness is formed adjacent to the first region.

13. The phase shift mask as claimed in claim 8, wherein a boundary between the portion of the first thickness and the portion of the second thickness is near the center between the first region and the second region.

14. The phase shift mask as claimed in claim 8, wherein the exposure light has a transmissivity of less than 1% both in the portion of the first thickness and the portion of the second thickness.

15. A method of manufacturing a phase shift mask comprising:
a light shielding film forming step of forming a light shielding film that shields exposure light on a transparent substrate;
a first light shielding film etching step of selectively etching the light shielding film formed in the light shielding film forming step;
a substrate etching step of selectively etching the transparent substrate etched in the first light shielding film etching step and having an exposed surface of the transparent substrate; and
a second light shielding film etching step of selectively etching the light shielding film not etched in the first light shielding film so that the light shielding film has a plurality of film thicknesses.

16. The method of manufacturing a phase shift mask as claimed in claim 15, wherein in the substrate etching step, an anisotropic etching method is used.

17. The method of manufacturing a phase shift mask as claimed in claim 15, wherein in the substrate etching step, selective etching is performed so that etched and unetched regions are alternately arranged with the light shielding film interposed therebetween.

18. The method of manufacturing a phase shift mask as claimed in claim 15, wherein in the second light shielding film etching step, a portion nearer to the region etched in the substrate etching step is etched.

19. The method of manufacturing a phase shift mask as claimed in claim 15, wherein in the second light shielding film etching step, etching is performed so that the etched portion of the light shielding film has a film thickness reduced to generally a half.

20. The method of manufacturing a phase shift mask as claimed in claim 15, wherein the light shielding film is formed from Cr (chromium), and in the second light shielding film etching step, the light shielding film that has been selectively etched has a thickness of 60 nm or greater, and the light shielding film that has not been selectively etched has a thickness of 110 nm or greater.
